(19) United States
(12) Patent Application Publication
(10) Pub. No.: US 2025/0234568 A1
(43) Pub. Date: Jul. 17, 2025

(54) CAPACITOR DEVICE WITH MULTI-LAYER DIELECTRIC STRUCTURE

(71) Applicant: Taiwan Semiconductor Manufacturing Company, Ltd., Hsinchu (TW)

(72) Inventors: Yu-En JENG, Taichung (TW); Hsiang-Ku SHEN, Hsinchu City (TW); Cheng-Hao HOU, Hsinchu City (TW); Chen-Chiu HUANG, Taichung City (TW); Dian-Hau CHEN, Hsinchu (TW)

(73) Assignee: Taiwan Semiconductor Manufacturing Company, Ltd., Hsinchu (TW)

(21) Appl. No.: 19/095,348

(22) Filed: Mar. 31, 2025

Related U.S. Application Data
(63) Continuation of application No. 17/569,279, filed on Jan. 5, 2022, now Pat. No. 12,266,681.
(60) Provisional application No. 63/279,374, filed on Nov. 15, 2021.

(51) Int. Cl. H10D 1/68; H10B 12/00

(52) U.S. Cl. CPC H10D 1/68; H10B 12/0335

(57) ABSTRACT

Structures of a semiconductor device structure are provided. The semiconductor device structure includes a first insulating layer formed over a semiconductor substrate and an interconnect structure formed in the first insulating layer. The semiconductor device structure also includes a second insulating layer formed over the first insulating layer and a capacitor device embedded in the second insulating layer. The capacitor device includes a first capacitor electrode layer electrically connected to the interconnect structure, a capacitor insulating stack formed over the first capacitor electrode layer and a second capacitor electrode layer formed over the capacitor insulating stack. The capacitor insulating stack includes first layers alternatingly stacked with second layers.

### PRIORITY CLAIM AND CROSS-REFERENCE

This Application is a Continuation of pending U.S. patent application Ser. No. 17/569,279, filed Jan. 5, 2022, which claims the benefit of U.S. Provisional Application No. 63/279,374, filed on Nov. 15, 2021, and entitled “CAPACITOR DEVICE WITH MULTI-LAYER DIELECTRIC STRUCTURE”, the entirety of which are incorporated by reference herein.

### BACKGROUND

The semiconductor industry has experienced rapid growth and demands for highly integrated semiconductor devices are increasing. Technological advances in integrated circuit (IC) design and materials have produced generations of ICs. Each generation has smaller and more complex circuits than previous generations.

Semiconductor devices may include active and/or passive devices such as transistors and capacitors. For example, the capacitors are a passive two-terminal electrical component used to store energy electro-statically in an electric field. The forms of practical capacitors vary widely, but all contain at least two electrical conductors separated by a dielectric (insulator). Capacitors are widely used in electronic circuits, such as in a memory device. For integrated circuits and for DRAM devices in particular, the use of metal-insulator-metal (MIM) capacitors has become widespread in recent years.

Although existing MIM capacitors and methods of fabricating those capacitors have been generally adequate for their intended purposes, they have not been entirely satisfactory in all respects. For example, although the MIM capacitor with thin insulator provides a large capacitance, large leakage current may be induced due to the thin capacitor insulator.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A to 1E show cross-sectional views of various stages of a semiconductor device structure having a capacitor device, in accordance with some embodiments.

FIG. 2 shows an enlarged cross-sectional view of a region 240 shown in FIG. 1D, in accordance with some embodiments.

FIG. 3 shows an enlarged cross-sectional view of a region 240 shown in FIG. 1D, in accordance with some embodiments.

FIG. 4 shows an enlarged cross-sectional view of a region 240 shown in FIG. 1D, in accordance with some embodiments.

FIG. 5 shows an enlarged cross-sectional view of a region 240 shown in FIG. 1D, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the FIG.s. The spatially relative terms are intended to encompass different orientations of the device in use or operation in addition to the orientation depicted in the FIG.s. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. Where applicable, the term “substantially” may also relate to 90% or higher, such as 95% or higher, especially 99% or higher, including 100%. Furthermore, terms such as “substantially parallel” or “substantially perpendicular” are to be interpreted as not to exclude insignificant deviation from the specified arrangement and may include for example deviations of up to 10°. The word “substantially” does not exclude “completely” e.g. a composition which is “substantially free” from Y may be completely free from Y.

Terms such as “about” in conjunction with a specific distance or size are to be interpreted so as not to exclude insignificant deviation from the specified distance or size and may include for example deviations of up to 10%. The term “about” in relation to a numerical value x may mean x±5 or 10%.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

Embodiments for manufacturing semiconductor device structures are provided. The semiconductor device structures may include a capacitor device, such as a metal-insulator-metal (MIM) or metal-insulator-semiconductor (MIS) capacitor, which is embedded in an insulating layer over a semiconductor substrate and electrically connected to a conductive feature and/or an interconnect structure thereunder. The capacitor device includes an insulating stack formed between two electrodes and including first layers alternatingly arranged with second layers. A dielectric constant and/or a lattice constant of the first layer are different than a dielectric constant and/or a lattice constant of the second layer.

In the insulating stack, the lowermost layer (e.g., the first or second layer) exerts a tensile or compressive stress on the overlying layers, so that the formed insulating stack has a monoclinic or tetragonal crystal phase. As a result, the capacitor insulating stack can provide a higher dielectric constant than a single bulk capacitor insulator. When the capacitor insulating stack and the single bulk capacitor insulator have the same thickness, larger capacitance can be obtained in the capacitor device with the capacitor insulating stack.

In addition, the grain sizes of the first layer and the second layer in the capacitor insulating stack are smaller than that of the single bulk capacitor insulator. As a result, the grain boundaries in the capacitor insulating stack are smaller than those of the single bulk capacitor insulator, thereby reducing the leakage path. Therefore, lower leakage current can also be obtained in the capacitor device with the capacitor insulating stack.

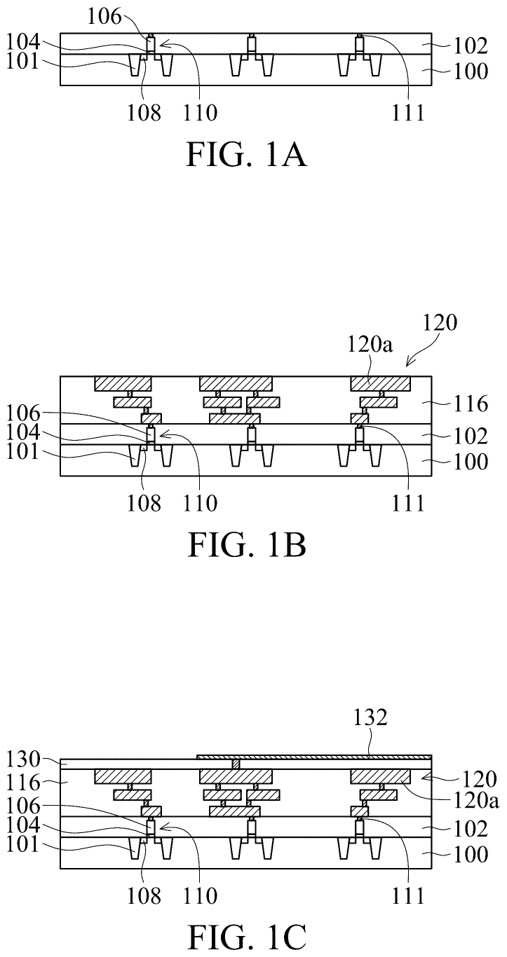

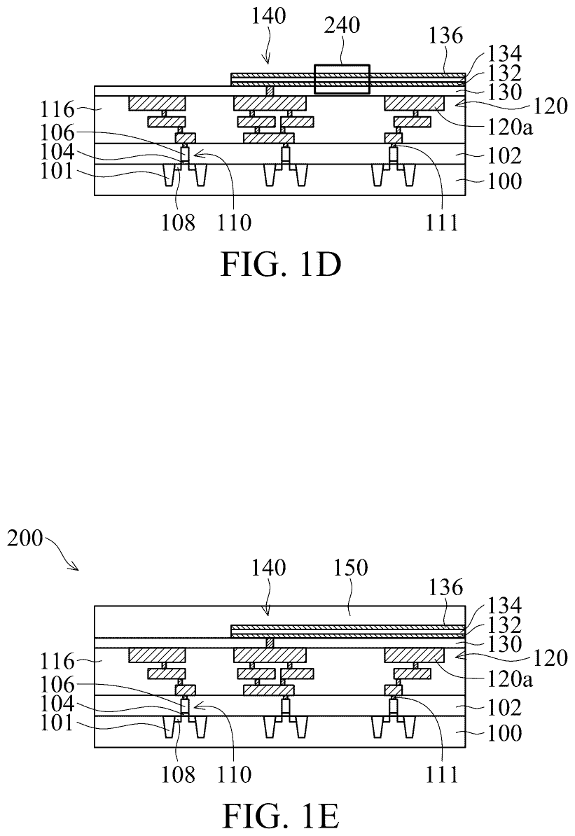

Embodiments for a semiconductor device structure and method for forming the same are provided. FIGS. 1A to 1E show cross-sectional views of various stages of a semiconductor device structure 200, in accordance with some embodiments. In some embodiments, the semiconductor device structure 200 includes a capacitor device 140 (such as a MIM or MIS capacitor device) formed over semiconductor devices, such as planar transistors with multiple interconnection layers formed thereover in later figures. In some other embodiments, the semiconductor devices are fin field effect transistors (FinFETs), gate-all-around (GAA) transistors, or other types of active devices. The semiconductor devices are formed by the front-end of line (FEOL) process. The overlying capacitor device 140 are formed by the back-end of line (BEOL) process that includes the formation of the multiple interconnection layers to be electrically connected between the one or more semiconductor devices (e.g., the transistors) and the capacitor device 140.

In some embodiments, a substrate 100, such as a bulk semiconductor substrate or a silicon-on-insulator (SOI) substrate is provided, as shown in FIG. 1A. An SOI substrate includes an insulator layer below a thin semiconductor layer that is the active layer of the SOI substrate. The semiconductor of the active layer and the bulk semiconductor generally includes the crystalline semiconductor material silicon. Alternatively or additionally, the substrate 100 may include other elementary semiconductor materials (e.g., germanium). In some embodiments, the substrate 100 is made of a compound semiconductor (e.g., GaAs, AlAs, InAs, GaN, AlN, InP, SiC or the like). In some embodiments, the substrate 100 is made of an alloy semiconductor such as silicon germanium, silicon germanium carbide, gallium arsenic phosphide, or gallium indium phosphide. In some embodiments, the substrate 100 includes an epitaxial layer. For example, the substrate 100 has an epitaxial layer overlying a bulk semiconductor. The semiconductor materials mentioned above may be doped or undoped. Other substrates that may be used include multi-layered substrates, gradient substrates, or hybrid orientation substrates.

An isolation structure 101, such as shallow trench isolation (STI) structures is formed in the substrate 100 to isolate the semiconductor devices in the substrate 100, as shown in FIG. 1A in accordance with some embodiments. In some embodiments, an insulating layer 102 is formed over the top surface of the substrate 100 and gate structures 110 are embedded in the insulating layer 102, after the formation of the isolation structure 101.

In some embodiments, the gate structure 110 includes a gate dielectric layer 104 and a gate electrode layer 106 formed over the gate dielectric layer 104. Source and drain regions 108 are formed in the substrate 100 and next to the corresponding gate structure 110 prior to the formation of the insulating layer 102 and after the formation of the gate structures 110. The gate structure 110 embedded in the insulating layer 102 and the corresponding source and drain regions 108 formed in the substrate 100 forms a transistor. Afterwards, contact structures 111 (such as contact plugs) are formed in the insulating layer 102 and electrically coupled to the underlying gate structures 110, respectively.

In some embodiments, the insulating layer 102 is an inter-layer dielectric (ILD) layer that is formed over the substrate 100 and fills the space between the gate structures 110 of transistors. The insulating layer 102 is employed to electrically isolate the substrate 100 from the overlying conductive features/layers. In some embodiments, the insulating layer 102 includes silicon oxide, silicon nitride (SiₓN_{y}), silicon oxynitride, silicon nitride (SiₓN_{y}), silicon carbon nitride, tetraethoxysilane (TEOS) oxide, phospho silicate glass (PSG), boro silicate glass (BSG), boron-doped phospho silicate glass (BPSG), fluorine-doped silicate glass (FSG), or the like, or a combination thereof. The insulating layer 102 may be formed by chemical vapor deposition (CVD), flowable CVD (FCVD), plasma enhanced CVD (PECVD), low pressure CVD (LPCVD), atomic layer deposition (ALD), physical vapor deposition (PCD), spin-on coating, or any other suitable deposition process.

In some embodiments, the contact structures 111 formed in the insulating layer 102 are also used to electrically connect the gate structures 110 to the overlying metal lines and vias. The contact structures 111 are formed of a conductive material, such as tungsten, aluminum, copper, titanium, tantalum, titanium nitride, tantalum nitride, or alloys thereof. The formation of the contact structures 111 may include forming contact openings in the insulating layer 102, filling a conductive material into the contact openings, and performing a planarization process (such as a chemical mechanical polishing (CMP) process or a mechanical grinding process) to substantially level the top surfaces of the contact structures 111 with the top surface of the insulating layer 102.

After the contact structures 111 are formed, an insulating layer 116 and an interconnect structure 120 are successively formed over the insulating layer 102, as shown in FIG. 1B in accordance with some embodiments. The interconnect structure 120 that is electrically connected to the contact structures 111 may be used as a redistribution (RDL) structure for routing. The interconnect structure 120 includes multiple metal lines and vias formed in insulating layer 116 (also referred to as an inter-metal dielectric (IMD) layer). The metal lines at the same level are collectively referred to as a metal layer hereinafter. In some embodiments, the interconnect structure 120 has metal layers that include the uppermost metal layer 120a, and which are interconnected by conductive vias. The metal layers and conductive vias may be formed of copper or copper alloys, but they can also be formed of other metals.

The insulating layer 116 may be a single layer or a multi-layer structure and be formed of silicon oxide, silicon carbide (SiC), silicon nitride (SiₓN_{y}), silicon oxynitride, or low-k dielectric materials. The low dielectric constant (low-k) dielectric materials may include a carbon-containing low-k dielectric material, hydrogen silsesquioxane (HSQ), methylsilsesquioxane (MSQ), or the like. The insulating layer 116 may be formed by chemical vapor deposition (CVD), flowable CVD (FCVD), plasma enhanced CVD (PECVD), low pressure CVD (LPCVD), atomic layer deposition (ALD), physical vapor deposition (PCD), spin-on coating, or any other suitable deposition process.

The formation of metal layers and vias may include single damascene processes and/or dual damascene processes. In a single damascene process, trenches are first formed in the insulating layer 116, followed by filling the trenches with a conductive material. A planarization process (e.g., a chemical mechanical polishing (CMP) process or a mechanical grinding process) is then performed to remove any excess portions of the conductive material that is higher than the top surface of the insulating layer 116, leaving a metal layer in each of the trenches.

In addition, in a dual damascene process, both trench and via openings are formed in the insulating layer 116r, with the via opening underlying and connected to the corresponding trench. The conductive material is then filled into the trenches and the via openings to form a metal layer and vias. The conductive material may include a diffusion barrier layer and a metal material over the diffusion barrier layer. The metal material may be made of copper (Cu), copper alloy, aluminum (Al), aluminum alloy, tungsten (W), tungsten alloy, titanium (Ti), titanium alloy, tantalum (Ta) or tantalum alloy. The metal layers and vias may be formed by electroplating, electroless plating, printing, chemical vapor deposition (CVD), or physical vapor deposition (PVD). The diffusion barrier layer may include titanium, titanium nitride, tantalum, tantalum nitride, or the like.

After the interconnect structure 120 is formed, a capacitor device 140 is formed over the interconnect structure 120 and electrically connected to the interconnect structure 120, as shown in FIGS. 1C to 1D in accordance with some embodiments. In some embodiments, an optional etching stop layer (not shown) is formed over the interconnect structure 120, and an insulating layer 130 is formed over the etching stop layer, as shown in FIG. 1C. The etching stop layer may be made of silicon carbide (SiC), silicon nitride (SiₓN_{y}), silicon carbonitride (SiCN), silicon oxycarbide (SiOC), silicon oxycarbon nitride (SiOCN), or another applicable material. The etching stop layer may be formed by a deposition process, such as chemical vapor deposition (CVD), physical vapor deposition (PVD), atomic layer deposition (ALD), or another applicable process. In addition, the insulating layer 130 may be made of undoped silicate glass (USG), silicon oxide, or another applicable material. The insulating layer 130 may be formed by a deposition process, such as chemical vapor deposition (CVD), physical vapor deposition (PVD), atomic layer deposition (ALD), or another applicable process.

Afterwards, a capacitor electrode layer 132 is formed over the insulating layer 130 and electrically connected to the underlying interconnect structure 120 through one or more vias formed in the insulating layer 130, in accordance with some embodiments. The capacitor electrode layer 132 is also referred to as a bottom electrode layer of the subsequently formed capacitor device. The capacitor electrode layer 132 is made of a conductive material, such as a metal material, a metal alloy material, or a doped semiconductor material. For an example, the capacitor electrode layer 132 is made of a metal or metal alloy, including titanium (Ti), tantalum (Ta), copper (Cu), platinum (Pt), tungsten (W), aluminum (Al), titanium nitride (TiN), tantalum nitride (TaN), tantalum aluminum nitride (TaAlN), copper alloy, aluminum (Al) alloy, copper aluminum alloy (AlCu), or tungsten (W) alloy or another applicable material. For another example, the capacitor electrode layer 132 is made of a group IV semiconductor material (e.g., Si, Ge, or SiGe) or a group III-V semiconductor material (e.g., GaAs, GaN, InGaAs, or InGaN) that is heavily doped with p-type or n-type dopants.

The formation of the capacitor electrode layer 132 includes deposition, photolithography, and etching processes. The deposition processes include chemical vapor deposition (CVD), physical vapor deposition (PVD), atomic layer deposition (ALD), or another applicable process. The photolithography processes include photoresist coating (e.g., spin-on coating), soft baking, mask aligning, exposure, post-exposure baking, developing photoresist, rinsing and drying (e.g., hard baking). The etching process includes a dry etching process or a wet etching process. In some embodiments, after the photolithography processes, a cleaning process is performed to remove some residue remaining on the capacitor electrode layer 132.

Afterwards, a capacitor insulating stack 134 is formed over the capacitor electrode layer 132, and a capacitor electrode layer 136 is formed over the capacitor insulating stack 134, as shown in FIG. 1D in accordance with some embodiments of the disclosure. In some embodiments, the capacitor electrode layer 136 is also referred to as a top electrode layer of the subsequently formed capacitor device. The capacitor electrode layer 136 is made of a conductive material, such as a metal material, a metal alloy material, or a doped semiconductor material. For an example, the capacitor electrode layer 136 is made of a metal or metal alloy, including titanium (Ti), tantalum (Ta), copper (Cu), platinum (Pt), tungsten (W), aluminum (Al), titanium nitride (TiN), tantalum nitride (TaN), tantalum aluminum nitride (TaAlN), copper alloy, aluminum (Al) alloy, copper aluminum alloy (AlCu), or tungsten (W) alloy or another applicable material. For another example, the capacitor electrode layer 136 is made of a group IV semiconductor material (e.g., Si, Ge, or SiGe) or a group III-V semiconductor material (e.g., GaAs, GaN, InGaAs, or InGaN) that is heavily doped with p-type or n-type dopants.

The formation of the capacitor electrode layer 136 includes deposition, photolithography, and etching processes. The deposition processes include chemical vapor deposition (CVD), physical vapor deposition (PVD), atomic layer deposition (ALD), or another applicable process. The etching process includes a dry etching process or a wet etching process. In some embodiments, after the photolithography processes, a cleaning process is performed to remove some residue remaining on the capacitor electrode layer 136.

The capacitor device 140 includes the capacitor electrode layer 132, the capacitor insulating stack 134, and the capacitor electrode layer 136 to form an MIM or MIS capacitor device. The capacitor electrode layer 132 is a bottom electrode of the capacitor device 140, and the capacitor electrode layer 136 is the top electrode of the capacitor device 140. The capacitor device 140 is electrically connected to the uppermost metal layer 120a of the interconnect structure 120 through one or more vias formed between the capacitor electrode layer 132 and the interconnect structure 120 in accordance with some embodiments. In some other embodiments, the capacitor device 140 is electrically connected to another interconnect structure (not shown) that is formed in the subsequently formed insulating layer over the insulating layer 130 and is electrically connected to the uppermost metal layer 120a of the interconnect structure 120.

In some embodiments, the capacitor insulating stack 134 has a multi-layer structure and is made of high-k dielectric materials. The high-k dielectric material has a dielectric constant (k value) that is substantially equal to or greater than 4. Examples of high-k dielectric material may include hafnium oxide (HfO₂), zirconium oxide (ZrO₂), aluminum oxide (Al₂O₃), lanthanum oxide (La₂O₃), lanthanum aluminum oxide (LaAlO₃), titanium oxide (TiₓO_{y}, wherein x is a real number and y is a real number), tantalum oxide (TaₓO_{y}, wherein x is a real number and y is a real number), titanium oxide nitride (TiₓO_{y}N_{z}, wherein x is a real number, y is a real number and z is a real number), tantalum oxide nitride (TaₓO_{y}N_{z}, wherein x is a real number, y is a real number and z is a real number) and the like.

In some embodiments, the capacitor insulating stack 134 that has a multi-layer structure includes first layers (which are also referred to first capacitor dielectric layers) alternatingly stacked with second layers (which are also referred to second capacitor dielectric layers). Moreover, the first capacitor dielectric layer is made of a different material than the second capacitor dielectric layer. As a result, the dielectric constant of the first capacitor dielectric layer is different than the dielectric constant of the second capacitor dielectric layer. Moreover, the lattice constant of the first capacitor dielectric layer is also different than the lattice constant of the second capacitor dielectric layer.

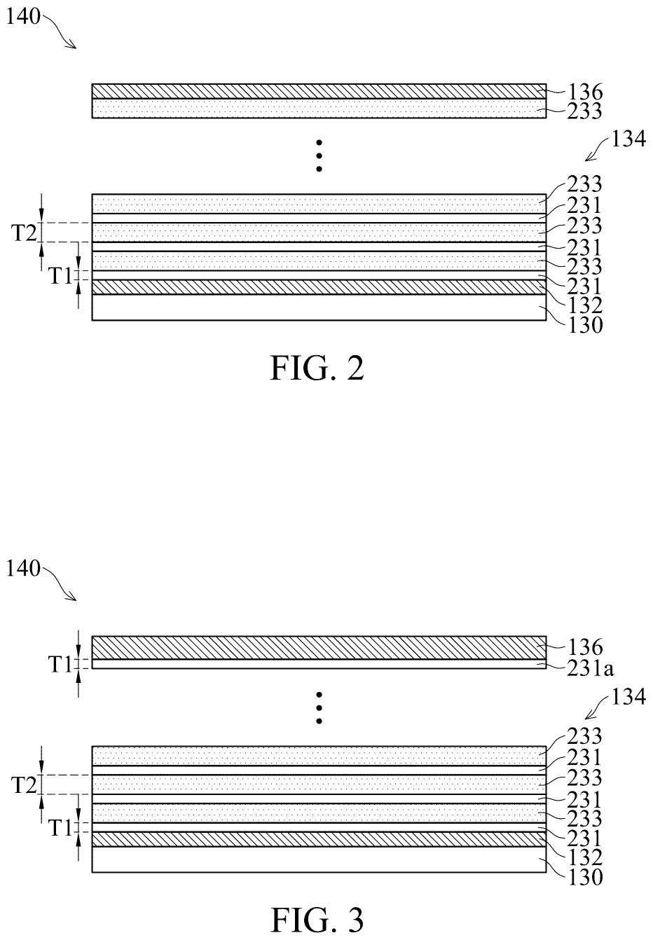

FIG. 2 shows an enlarged cross-sectional view of a region 240 shown in FIG. 1D, in accordance with some embodiments. The region 240 shows the detailed configuration of the capacitor insulating stack 134 shown in FIG. 1D, in accordance with some embodiments. As shown in FIG. 2, the capacitor insulating stack 134 formed between the capacitor electrode layer 132 and the capacitor electrode layer 136 includes capacitor dielectric layers 231 alternatingly stacked with capacitor dielectric layers 233. In some embodiments, the number of capacitor dielectric layers 231 is equal to the number of capacitor dielectric layers 233, and the number of capacitor dielectric layers 231 is greater than 2 (e.g., 3, 4, 5, 6, and so forth). In those cases, one of the capacitor dielectric layers 231 (e.g., the lowermost layer of the capacitor dielectric layers 231) is in direct contact with the capacitor electrode layer 132, and one of the capacitor dielectric layers 233 (e.g., the uppermost layer of the capacitor dielectric layers 233) is between and in direct contact with the capacitor electrode layer 136 and one of the capacitor dielectric layers 231 (e.g., the uppermost layer of the capacitor dielectric layers 231).

In some embodiments, each of the capacitor dielectric layers 231 has a thickness T1 and each of the capacitor dielectric layers 233 has a thickness T2 different than the thickness T1. For example, the capacitor dielectric layer 231 is made of HfO₂, and the capacitor dielectric layer 233 is made of ZrO₂. In this case, the dielectric constant of the capacitor dielectric layer 231 is lower than the dielectric constant of the capacitor dielectric layer 233. Further, the lattice constant of the capacitor dielectric layer 231 is also lower than the lattice constant of the capacitor dielectric layer 233. In addition, the thickness T1 of the capacitor dielectric layer 231 is less than the thickness T2 of the capacitor dielectric layer 233.

In such a configuration of the capacitor insulating stack 134, the capacitor dielectric layers 231 alternatingly arranged with capacitor dielectric layers 233 form a superlattice multi-layer structure that separates the capacitor electrode layer 132 and the capacitor electrode layer 136. The lowermost capacitor dielectric layers 231 may exert a compressive stress to the overlying deposited capacitor dielectric layers, so that the lattice structure of the capacitor insulating stack 134 has a tetragonal crystal phase. As a result, the capacitor insulating stack 134 provides a higher dielectric constant than a single bulk capacitor insulator used in the typical MIM or MIS capacitor device. Therefore, the capacitance of the capacitor device 140 with the capacitor insulating stack 134 can be improved.

In addition, the grain sizes of the capacitor dielectric layers 231 and 233 can be reduced, so that the grain sizes of the capacitor dielectric layers 231 and 233 are smaller than the grain size of the single bulk capacitor insulator used in the typical MIM or MIS capacitor device. As a result, the grain boundaries in capacitor dielectric layers 231 and 233 are smaller than those of the single bulk capacitor insulator in the typical MIM or MIS capacitor device, thereby reducing the leakage path. Therefore, lower leakage current can also be obtained in the capacitor device 140 with the capacitor insulating stack 134.

Many variations and/or modifications can be made to embodiments of the disclosure. For example, the configuration of the capacitor insulating stack 134 shown in FIG. 2 includes the lowermost layer of the capacitor dielectric layers 231 in direct contact with the capacitor electrode layer 132, and the uppermost layer of the capacitor dielectric layers 233 in direct contact with the capacitor electrode layer 136, but embodiments of the disclosure are not limited thereto. FIG. 3 shows an enlarged cross-sectional view of a region 240 shown in FIG. 1D, in accordance with some embodiments. Similarly, the materials and formation methods of the capacitor insulating stack shown in FIG. 2 may also be applied in the embodiments illustrated in FIG. 3, and may be therefore not repeated.

As shown in FIG. 3, the capacitor insulating stack 134 formed between the capacitor electrode layer 132 and the capacitor electrode layer 136 includes capacitor dielectric layers 231 alternatingly stacked with capacitor dielectric layers 233. Moreover, the capacitor insulating stack 134 further includes a capacitor dielectric layer 231a formed over the capacitor dielectric layers 231 and 233. In some embodiments, the capacitor dielectric layer 231a is made of a material that is the same as the material of the capacitor dielectric layer 231. That is, the capacitor dielectric layer 231a can serve as an additional capacitor dielectric layer 231.

Similarly, the number of capacitor dielectric layers 231 is equal to the number of capacitor dielectric layers 233, and the number of capacitor dielectric layers 231 is greater than 2. In those cases, one of the capacitor dielectric layers 231 (e.g., the lowermost layer of the capacitor dielectric layers 231) is in direct contact with the capacitor electrode layer 132, and the capacitor dielectric layer 231a is between and in direct contact with the capacitor electrode layer 136 and one of the capacitor dielectric layers 233 (e.g., the uppermost layer of the capacitor dielectric layers 233).

In some embodiments, each of the capacitor dielectric layers 231 and the capacitor dielectric layer 231a has a thickness T1 and each of the capacitor dielectric layers 233 has a thickness T2 different than the thickness T1. For example, the capacitor dielectric layer 231 and the capacitor dielectric layer 231a are made of HfO₂, and the capacitor dielectric layer 233 is made of ZrO₂.

In such a configuration of the capacitor insulating stack 134, the capacitor dielectric layers 231, 233 and 231a form a superlattice multi-layer structure that separates the capacitor electrode layer 132 and the capacitor electrode layer 136. Similarly, the lattice structure of the capacitor insulating stack 134 shown in FIG. 3 has a tetragonal crystal phase. Compared to the typical MIM or MIS capacitor device using the single bulk capacitor insulator, the capacitance of the capacitor device 140 with the capacitor insulating stack 134 can be improved, while reducing the leakage current.

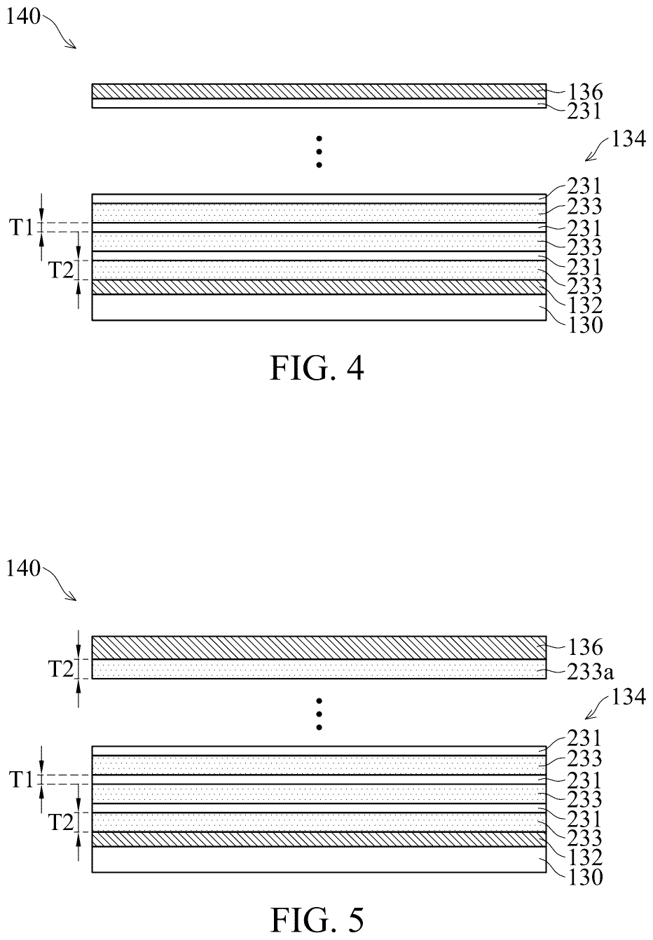

Many variations and/or modifications can be made to embodiments of the disclosure. For example, the configuration of the capacitor insulating stack 134 shown in FIG. 2 includes the lowermost layer of the capacitor dielectric layers 231 in direct contact with the capacitor electrode layer 132, and the uppermost layer of the capacitor dielectric layers 233 in direct contact with the capacitor electrode layer 136, but embodiments of the disclosure are not limited thereto. FIG. 4 shows an enlarged cross-sectional view of a region 240 shown in FIG. 1D, in accordance with some embodiments. Similarly, the materials and formation methods of the capacitor insulating stack shown in FIG. 2 may also be applied in the embodiments illustrated in FIG. 4, and may be therefore not repeated.

As shown in FIG. 4, the capacitor insulating stack 134 formed between the capacitor electrode layer 132 and the capacitor electrode layer 136 includes capacitor dielectric layers 233 alternatingly stacked with capacitor dielectric layers 231. Similarly, the number of capacitor dielectric layers 233 is equal to the number of capacitor dielectric layers 231, and the number of capacitor dielectric layers 233 is greater than 2 (e.g., 3, 4, 5, 6, and so forth). In those cases, one of the capacitor dielectric layers 233 (e.g., the lowermost layer of the capacitor dielectric layers 233) is in direct contact with the capacitor electrode layer 132, and one of the capacitor dielectric layers 231 (e.g., the uppermost layer of the capacitor dielectric layers 231) is between and in direct contact with the capacitor electrode layer 136 and one of the capacitor dielectric layers 233 (e.g., the uppermost layer of the capacitor dielectric layers 233).

In some embodiments, each of the capacitor dielectric layers 231 has a thickness T1 and each of the capacitor dielectric layers 233 has a thickness T2 different than the thickness T1. For example, the capacitor dielectric layer 231 is made of HfO₂, and the capacitor dielectric layer 233 is made of ZrO₂. In this case, the thickness T1 of the capacitor dielectric layer 231 is less than the thickness T2 of the capacitor dielectric layer 233.

In such a configuration of the capacitor insulating stack 134, the capacitor dielectric layers 233 alternatingly arranged with capacitor dielectric layers 231 also form a superlattice multi-layer structure that separates the capacitor electrode layer 132 and the capacitor electrode layer 136. The lowermost capacitor dielectric layers 233 may exert a tensile stress to the overlying deposited capacitor dielectric layers, so that the lattice structure of the capacitor insulating stack 134 has a monoclinic crystal phase. As a result, the capacitor insulating stack 134 provides a higher dielectric constant than a single bulk capacitor insulator used in the typical MIM or MIS capacitor device, but a lower dielectric constant than the configuration of the insulating stack 134 shown in FIGS. 2 and 3. Therefore, the capacitance of the capacitor device 140 with the capacitor insulating stack 134 can be improved compared to the typical MIM or MIS capacitor device using the single bulk capacitor insulator.

In addition, the lattice structure of the capacitor insulating stack 134 shown in FIG. 4 has a monoclinic crystal phase, rather than a tetragonal crystal phase, the grain sizes of the capacitor dielectric layers 231 and 233 can be further reduced as compared to those shown in FIGS. 2 and 3. Therefore, the leakage current can be reduced further.

Many variations and/or modifications can be made to embodiments of the disclosure. For example, the configuration of the capacitor insulating stack 134 shown in FIG. 4 includes the lowermost layer of the capacitor dielectric layers 233 in direct contact with the capacitor electrode layer 132, and the uppermost layer of the capacitor dielectric layers 231 in direct contact with the capacitor electrode layer 136, but embodiments of the disclosure are not limited thereto. FIG. 4 shows an enlarged cross-sectional view of a region 240 shown in FIG. 1D, in accordance with some embodiments. Similarly, the materials and formation methods of the capacitor insulating stack shown in FIG. 4 may also be applied in the embodiments illustrated in FIG. 5, and may be therefore not repeated.

As shown in FIG. 5, the capacitor insulating stack 134 formed between the capacitor electrode layer 132 and the capacitor electrode layer 136 includes capacitor dielectric layers 233 alternatingly stacked with capacitor dielectric layers 231. Moreover, the capacitor insulating stack 134 further includes a capacitor dielectric layer 233a formed over the capacitor dielectric layers 233 and 231. In some embodiments, the capacitor dielectric layer 233a is made of a material that is the same as the material of the capacitor dielectric layer 233. That is, the capacitor dielectric layer 233a can serve as an additional capacitor dielectric layer 233.

Similarly, the number of capacitor dielectric layers 231 is equal to the number of capacitor dielectric layers 233, and the number of capacitor dielectric layers 231 is greater than 2. In those cases, one of the capacitor dielectric layers 233 (e.g., the lowermost layer of the capacitor dielectric layers 233) is in direct contact with the capacitor electrode layer 132, and the capacitor dielectric layer 233a is between and in direct contact with the capacitor electrode layer 136 and one of the capacitor dielectric layers 231 (e.g., the uppermost layer of the capacitor dielectric layers 231).

In some embodiments, each of the capacitor dielectric layers 233 and the capacitor dielectric layer 233a has a thickness T2 and each of the capacitor dielectric layers 231 has a thickness T1 different than the thickness T2. For example, the capacitor dielectric layer 233 and the capacitor dielectric layer 233a are made of ZrO₂, and the capacitor dielectric layer 231 is made of HfO₂.

In such a configuration of the capacitor insulating stack 134, the capacitor dielectric layers 233, 231 and 233a form a superlattice multi-layer structure that separates the capacitor electrode layer 132 and the capacitor electrode layer 136. Similarly, the lattice structure of the capacitor insulating stack 134 shown in FIG. 5 has a monoclinic crystal phase. Compared to the typical MIM or MIS capacitor device using the single bulk capacitor insulator, the capacitance of the capacitor device 140 with the capacitor insulating stack 134 can be improved, while reducing the leakage current.

After the capacitor device 140 is formed, an insulating layer 150 is formed over the capacitor device 140, as shown in FIG. 1E in accordance with some embodiments. In some embodiments, the material and the method used for formation of the insulating layer 150 are the same as or similar to those used for formation of the insulating layer 116 and/or the insulating layer 130. For example, the insulating layer 150 (also referred to as an IMD layer) may be a single layer or a multi-layer structure and be formed of silicon oxide, silicon carbide (SiC), silicon nitride (SiₓN_{y}), silicon oxynitride, or low-k dielectric materials. The low dielectric constant (low-k) dielectric materials may include a carbon-containing low-k dielectric material, hydrogen silsesquioxane (HSQ), methylsilsesquioxane (MSQ), or the like. The insulating layer 150 may be formed by chemical vapor deposition (CVD), flowable CVD (FCVD), plasma enhanced CVD (PECVD), low pressure CVD (LPCVD), atomic layer deposition (ALD), physical vapor deposition (PCD), spin-on coating, or any other suitable deposition process.

In some other embodiments, the insulating layers 130 and 142 are sometimes collectively referred to as a passivation structure. Therefore, the capacitor device 140 is embedded in the passivation structure that includes the insulating layers 130 and 142.

Embodiments of a semiconductor device structure are provided. The semiconductor device structure includes a capacitor device formed in an insulating layer on a semiconductor substrate. The capacitor device includes a first electrode layer, a capacitor insulating stack formed over the first electrode layer, and a second electrode layer formed over the capacitor insulating stack. The capacitor insulating stack includes first layers alternatingly stacked with second layers. A dielectric constant and/or a lattice constant of the first layer are different than a dielectric constant and/or a lattice constant of the second layer. The first layers alternatingly stacked with second layers form a superlattice multi-layer structure. In the superlattice multi-layer structure, the lowermost layer (e.g., the first or second layer) exerts a tensile or compressive stress on the overlying layers, so that the formed capacitor insulating stack has a monoclinic or tetragonal crystal phase. As a result, the capacitor insulating stack can provide a higher dielectric constant than a single bulk capacitor insulator. Therefore, when the capacitor insulating stack and the single bulk capacitor insulator have the same thickness, larger capacitance can be obtained in the capacitor device with the capacitor insulating stack. Moreover, the grain sizes of the first layer and the second layer in the capacitor insulating stack are smaller than that of the single bulk capacitor insulator. As a result, the grain boundaries in the capacitor insulating stack are smaller than those of the single bulk capacitor insulator, thereby reducing the leakage path. Therefore, lower leakage current can also be obtained in the capacitor device with the capacitor insulating stack.

In some embodiments, a semiconductor device structure is provided. The semiconductor device structure includes a first insulating layer formed over a semiconductor substrate and an interconnect structure formed in the first insulating layer. The semiconductor device structure also includes a second insulating layer formed over the first insulating layer and a capacitor device embedded in the second insulating layer. The capacitor device includes a first capacitor electrode layer electrically connected to the interconnect structure, a capacitor insulating stack formed over the first capacitor electrode layer and a second capacitor electrode layer formed over the capacitor insulating stack. The capacitor insulating stack includes first layers alternatingly stacked with second layers. The dielectric constant of the first layer is different than the dielectric constant of the second layer.

In some embodiments, a semiconductor device structure is provided. The semiconductor device structure includes an insulating layer formed over a semiconductor substrate. The semiconductor device structure also includes a capacitor device embedded in the insulating layer. The capacitor device includes a first metal electrode layer, a second metal electrode layer formed over the first metal electrode layer, and first capacitor dielectric layers alternatingly stacked with second capacitor dielectric layers. The first capacitor dielectric layers and the second capacitor dielectric layers are formed between the first metal electrode layer and the second metal electrode layer, and the first capacitor dielectric layer is made of HfO₂, and the second capacitor dielectric layer is made of ZrO₂.

In some embodiments, a semiconductor device structure is provided. The semiconductor device structure includes a conductive feature formed over a semiconductor substrate and a metal-insulator-metal (MIM) capacitor device formed over and electrically connected to the conductive feature. The MIM capacitor has a bottom electrode layer and a top electrode layer that are separated by a superlattice multi-layer structure including first dielectric layers and second dielectric layers that are in an alternate arrangement. The second dielectric layer has a different lattice constant and a different thickness than the first dielectric layer.

In some embodiments, a semiconductor device structure is provided. The semiconductor device structure includes a conductive structure formed over a semiconductor substrate. The conductive structure includes a first via formed in a first insulating layer, a metal stack formed in a second insulating layer over the first insulating layer, and a second via formed in a third insulating layer over the second insulating layer. The second via is electrically connected to the first via through the metal stack. The semiconductor device structure also includes a capacitor device formed over the third insulating layer. The capacitor device includes a first electrode layer electrically connected to the second via, a high-k dielectric stack formed over the first capacitor electrode layer and having a dielectric constant equal to or greater than 4, and a second electrode layer formed over the high-k dielectric stack. The first electrode layer is made of a different conductive material than the second electrode layer.

In some embodiments, a semiconductor device structure is provided. The semiconductor device structure includes a first insulating layer and a capacitor device formed over the insulating layer. The capacitor device includes a first electrode layer, a capacitor insulating stack formed over the first capacitor electrode layer and having a lattice structure with a tetragonal crystal phase, and a second electrode layer formed over the capacitor insulating stack. The first electrode layer is made of a different conductive material than the second electrode layer. The semiconductor device structure also includes an active device formed below the first insulating layer and having a gate that is electrically connected to the first electrode layer.

In some embodiments, a semiconductor device structure is provided. The semiconductor device structure includes a first insulating layer and a capacitor device formed over the insulating layer. The capacitor device includes a first electrode layer, a capacitor insulating stack formed over the first capacitor electrode layer, and a second electrode layer formed over the capacitor insulating stack. The capacitor insulating stack includes a lowermost capacitor insulating layer that is made of HfO_{2,} a first capacitor insulating layer formed over the lowermost capacitor insulating layer, a second capacitor insulating layer formed over and in direct contact with the first capacitor insulating layer, and an uppermost capacitor insulating layer formed over the second capacitor insulating layer. The second capacitor insulating layer is made of a different material than the first capacitor insulating layer. The semiconductor device structure also includes a conductive feature formed in the first insulating layer and an interconnect structure including an uppermost metal layer bellow and connected to the conductive feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device structure, comprising:
a conductive structure formed over a semiconductor substrate, comprising:
a first via formed in a first insulating layer;
a metal stack formed in a second insulating layer over the first insulating layer; and
a second via formed in a third insulating layer over the second insulating layer, wherein the second via is electrically connected to the first via through the metal stack; and
a capacitor device formed over the third insulating layer, comprising:
a first electrode layer electrically connected to the second via;
a high-k dielectric stack formed over the first capacitor electrode layer and having a dielectric constant equal to or greater than 4; and
a second electrode layer formed over the high-k dielectric stack, wherein the first electrode layer is made of a different conductive material than the second electrode layer.

2. The semiconductor device structure as claimed in claim 1, further comprising a fin field effect transistor (FinFET) or a gate-all-around (GAA) transistor that has a gate electrically connected to the capacitor device through the first via, the metal stack, and the second via.

3. The semiconductor device structure as claimed in claim 1, wherein the high-k dielectric stack comprises:
a lowermost dielectric layer;
an uppermost dielectric layer formed over the lowermost dielectric layer; and
a middle dielectric layer formed between the lowermost dielectric layer and the uppermost dielectric layer,
wherein the lowermost dielectric layer is made of a material that is the same as that of the uppermost dielectric layer and different from that of the middle dielectric layer.

4. The semiconductor device structure as claimed in claim 3, wherein the lowermost dielectric layer is made of HfO₂.

5. The semiconductor device structure as claimed in claim 4, wherein the lowermost dielectric layer has a thickness that is less than a thickness of the middle dielectric layer.

6. The semiconductor device structure as claimed in claim 3, wherein the lowermost dielectric layer is made of ZrO₂.

7. The semiconductor device structure as claimed in claim 6, wherein the lowermost dielectric layer has a thickness that is greater than a thickness of the middle dielectric layer.

8. The semiconductor device structure as claimed in claim 1, wherein the first electrode layer is made of a semiconductor material doped with p-type or n-type dopants and the second electrode layer is made of a metal or metal alloy.

9. The semiconductor device structure as claimed in claim 1, wherein the second electrode layer is made of a semiconductor material doped with p-type or n-type dopants and the first electrode layer is made of a metal or metal alloy material.

10. A semiconductor device structure, comprising:
a first insulating layer;
a capacitor device formed over the insulating layer, comprising:
a first electrode layer;
a capacitor insulating stack formed over the first capacitor electrode layer and having a lattice structure with a tetragonal crystal phase; and
a second electrode layer formed over the capacitor insulating stack, wherein the first electrode layer is made of a different conductive material than the second electrode layer; and
an active device formed below the first insulating layer and having a gate that is electrically connected to the first electrode layer.

11. The semiconductor device structure as claimed in claim 10, further comprising:
a via passing through the first insulating layer and connected to the first electrode layer;
a second insulating layer separated the first insulating layer from the gate of the active device; and
an interconnect structure formed in the second insulating layer.

12. The semiconductor device structure as claimed in claim 11, wherein the interconnect structure comprises:
a lowermost metal layer electrically connected to the gate; and
an uppermost metal layer connected to the via.

13. The semiconductor device structure as claimed in claim 10, wherein the capacitor insulating stack comprises:
a lowermost insulating layer; and
an uppermost insulating layer formed over the lowermost insulating layer; and
a middle insulating layer formed between the lowermost insulating layer and the uppermost insulating layer,
wherein the lowermost insulating layer is made of a material that is different from that of the middle insulating layer.

14. The semiconductor device structure as claimed in claim 13, wherein the lowermost insulating layer and the uppermost insulating layer are made of HfO₂.

15. The semiconductor device structure as claimed in claim 13, wherein the middle insulating layer and the uppermost insulating layer are made of ZrO₂.

16. A semiconductor device structure, comprising:
a first insulating layer;
a capacitor device formed over the insulating layer, comprising:
a first electrode layer;
a capacitor insulating stack formed over the first electrode layer, comprising:
a lowermost capacitor insulating layer that is made of HfO₂;
a first capacitor insulating layer formed over the lowermost capacitor insulating layer;
a second capacitor insulating layer formed over and in direct contact with the first capacitor insulating layer, wherein the second capacitor insulating layer is made of a different material than the first capacitor insulating layer; and
an uppermost capacitor insulating layer formed over the second capacitor insulating layer; and
a second electrode layer formed over the capacitor insulating stack;
a conductive feature formed in the first insulating layer; and
an interconnect structure comprising an uppermost metal layer bellow and connected to the conductive feature.

17. The semiconductor device structure as claimed in claim 15, further comprising a transistor formed below the interconnect structure, wherein the interconnect structure further comprises a lowermost metal layer connected to a gate of the transistor.

18. The semiconductor device structure as claimed in claim 16, wherein the second capacitor insulating layer is made of a different material than the lower capacitor insulating layer, the first capacitor insulating layer, and the uppermost capacitor insulating layer.

19. The semiconductor device structure as claimed in claim 18, wherein the lower capacitor insulating layer, the first capacitor insulating layer, and the uppermost capacitor insulating layer are made of the same material.

20. The semiconductor device structure as claimed in claim 19, wherein the lower capacitor insulating layer is made of HfO₂.
